(19) United States
(12) Patent Application Publication
(10) Pub. No.: US 2006/0003488 A1
(43) Pub. Date: Jan. 5, 2006

(54) Display pixel and method of fabricating the same

(76) Inventor: Wei-Pang Huang, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/979,438

(22) Filed: Nov. 2, 2004

(30) Foreign Application Priority Data
Jul. 5, 2004 (TW) 93120110

(51) Int. Cl. H01L 29/08; H01L 51/00; H01L 35/24; H01L 51/40

(52) U.S. Cl. 438/99; 257/40

(57) ABSTRACT

A display pixel having higher aperture ratio and method of fabricating the same. The method of fabricating a display pixel in accordance with the invention includes the steps of providing a substrate and simultaneously forming a transistor and a rugged capacitor on adjacent portions thereof, wherein the rugged capacitor comprises a first conductive layer, a dielectric layer and a second conductive layer stacked over the substrate, respectively having a rugged surface. An organic light emitting diode (OLED) is then formed on a portion of the substrate adjacent to the transistor, wherein an anode thereof electrically connects to the transistor.

### BACKGROUND OF THE INVENTION

1. Field of the Invention

The present invention relates to a display pixel structure of an electroluminescence device, and in particular to a display pixel structure having higher aperture ratio of an organic light-emitting diode (OLED) and the method of fabricating the same.

2. Description of the Related Art

In the new generation of flat panel techniques, organic light emitting diode (OLED) display has advantages of self-luminescence, wide-view angle, thin profile, light weight, low driving voltage and simple process. In OLED display with a laminated structure, organic compounds such as dyes, polymers, or other luminescent materials serve as an organic luminescent layer and are disposed between cathode and anode. In accordance with the driving mode, OLED display is classified into passive matrix and active matrix types.

The active matrix OLED (AM-OLED) display is driven by electric currents, in which each of the matrix-array pixel regions has at least one thin film transistor (TFT), serving as a switch, to modulate the driving current based on the variation in capacitor storage potential so as to control the brightness and gray level of the pixel regions. At present, the AM-OLED display is driven by two TFTs in each pixel region, and, alternatively, the AM-OLED is driven by four TFTs in each pixel region.

As shown in FIG. 1, a schematic top view of an AM-OLED display driven by two TFTs in each pixel region, disclosed in U.S. Pat. No. 6,492,778 as related art, is illustrated. Each display pixel 10 thereof includes two individual TFT regions T1 and T2, a capacitor region C and an organic light-emitting diode (OLED) region 11. In TFT region T1, an untitled transistor is connected to the scan line 12 and source/drain regions (not shown) thereof are respectively connected to the data line 14 and the capacitor region C through proper contact structures, not shown for simplicity. In TFT region T2, another untitled transistor connects the capacitor region C and the OLED region 11 through proper contact structures (not shown) and also connects the source line 16 and the contact structure therebetween, also not shown.

In FIG. 2, a cross section along the A-A′ line in FIG. 1 showing a capacitor structure, generally a stacked capacitor, in the capacitor region C is illustrated. The stacked capacitor includes a first conductive layer 22, a dielectric layer 24 and a second conductive layer 26 sequentially stacked over a substrate 20. The stacked type capacitor occupies a predetermined portion, almost one third, of surfaces of each display pixel 10 to supply sufficient and continuous current for the OLED region 11 during pixel scan. However, since the capacitor region C for forming capacitor takes a great portion of the display pixel and the aperture ratio thereof contributed by the OLED region 11 therein is thus reduced.

Hence, there is a need for a method of fabricating display pixels having improved aperture ratio.

### SUMMARY OF THE INVENTION

Accordingly, an object of the invention is to provide a display pixel having higher aperture ratio and a method of fabricating the same. The aperture ratio in each display pixel can be improved through the size reduction of the capacitor region thereof. Size reduction of the capacitor region can be achieved by forming rugged capacitors and/or the use of high-k dielectric therein.

In the present invention, a display pixel having higher aperture ratio is provided, comprising a capacitor and an organic light emitting diode formed over a substrate, wherein the capacitor comprises a first conductive layer, a dielectric layer and a second conductive layer stacked over the substrate, respectively having a rugged surface. A transistor electrically connecting the capacitor and the organic light emitting diode is formed over the substrate.

Further, a method of fabricating a display pixel according to the present invention comprises the steps of providing a substrate and simultaneously forming a transistor and a rugged capacitor on adjacent portions of the substrate, wherein the rugged capacitor comprises a first conductive layer, a dielectric layer and a second conductive layer stacked over the substrate, respectively having a rugged surface. An organic light emitting diode (OLED) is then formed on a portion of the substrate adjacent to the transistor, wherein an anode thereof electrically connects the transistor.

In one embodiment of the present invention, the rugged surface in the capacitor region can be formed through etching of the buffer layer. In another embodiment of the present invention, the rugged surface in the capacitor region can be enabled by additionally formed hemispherical structures in the capacitor.

Moreover, another method of fabricating a display pixel according to the present invention comprises the steps of providing a substrate and simultaneously forming a transistor and a stacked capacitor on adjacent portions thereof, wherein the capacitor comprises a first conductive layer, a high-k dielectric layer and a second conductive layer stacked over the substrate. An organic light emitting diode (OLED) is then formed on a portion of the substrate adjacent to the transistor, wherein a cathode thereof electrically connects the transistor.

In another embodiment of the present invention, unit capacitance in the capacitor region is increased only by the use of high-k dielectric in the capacitor region.

Display pixels formed according to methods of the present invention have improved aperture ratio and power consumption thereof can be also improved.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic top view showing conventional pixel regions as referenced in the Related Art; FIG. 2 is a cross section along the A-A′ line in FIG. 1 showing the structure of a stacked capacitor in the Related art;

FIG. 3 is a schematic top view showing display pixels fabricated in accordance with the present invention;

FIGS. 4a-4d are schematic diagrams showing cross sections along A-A′ line in FIG. 3 during a process for fabricating display pixels according to one embodiment of the present invention;

FIGS. 5a-5d are schematic diagrams showing cross sections along B-B′ line in FIG. 3 during a process for fabricating display pixels according to one embodiment of the present invention;

FIGS. 6a-6b are schematic diagrams showing cross sections along A-A′ line in FIG. 3 during a process for fabricating display pixels according to another embodiment of the present invention;

FIGS. 7a-7b are schematic diagrams showing cross sections along B-B′ line in FIG. 3 during a process for fabricating display pixels according to another embodiment of the present invention;

FIGS. 8a-8b are schematic diagrams showing cross sections along A-A′ line in FIG. 3 during a process for fabricating display pixels according to a third embodiment of the present invention; and

FIGS. 9a-9b are schematic diagrams showing cross sections along B-B′ line in FIG. 3 during a process for fabricating display pixels according to a third embodiment of the present invention.

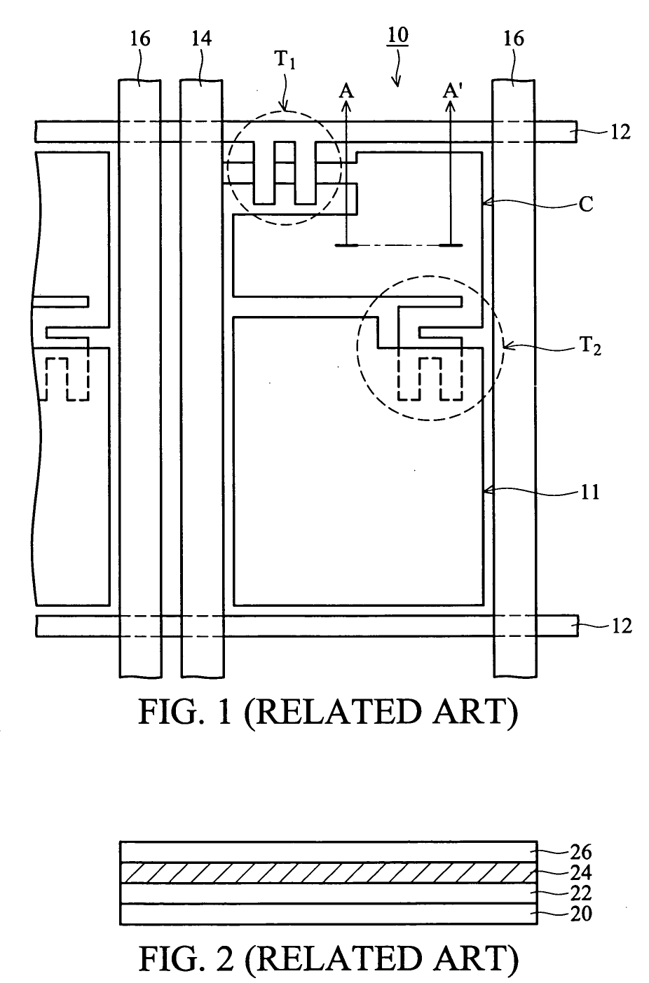

### DETAILED DESCRIPTION OF THE INVENTION

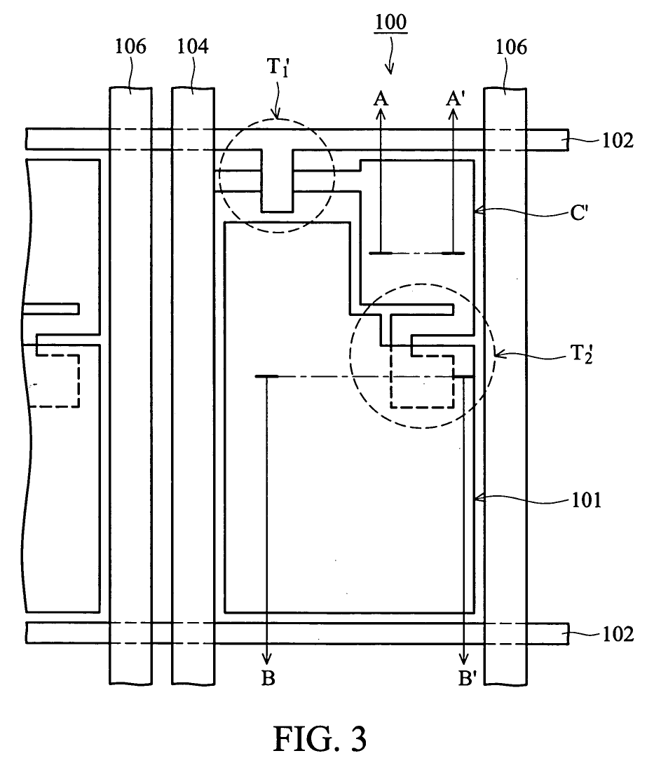

In FIG. 3, a schematic top view showing an AM-OLED display having pixel array according to an embodiment of the present invention is illustrated. In FIG. 3, each display pixel 100 includes two separate thin film transistor regions T1′ and T2′, a capacitor region C′ and an organic light-emitting diode (OLED) region 101. In the transistor region T1′, an untitled transistor is connected to the scan line 102 to store voltages for the other transistor region T2′ and source/drain regions (not shown) of the untitled transistor therein are respectively connected to data line 104 and the capacitor region C′ through proper contact structures but are not shown, for simplicity. In the transistor region T2′, another untitled capacitor is connected to a source line 106 and to the capacitor region C′ and the OLED region 101 through proper contact structures, not shown for simplicity. The untitled transistor in the transistor region T2′ serves as a driver to supply continuous currents, for the OLED region 101 during pixel scan.

In the present invention, unit capacitance within the capacitor region C′ is elevated and surfaces needed for the capacitor fabrication therein are thus reduced, as shown in FIG. 3. The reduced surfaces of the capacitor region C′ provide additional surfaces for the fabrication of the electroluminescence device of the OLED region 101. Thus, an OLED region 101 with higher illumination region can be thus fabricated and the aperture ratio of each display pixel 100 significantly increased.

Processes for fabricating the capacitor region C′ having elevated unit capacitance and the OLED region 101 occupying larger surfaces, which can be fabricated in combination with the transistor region T2′, in accordance with the present invention are respectively illustrated in the following embodiments.

### Embodiment 1

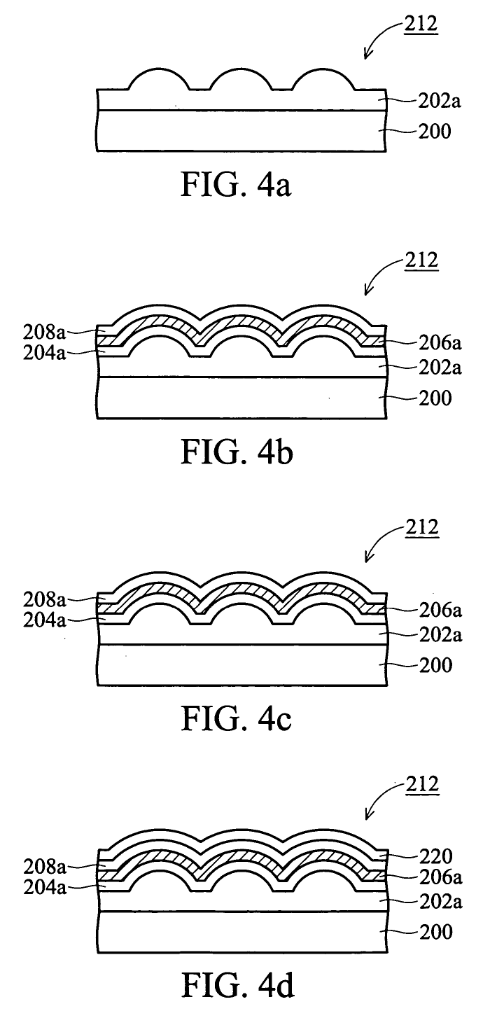

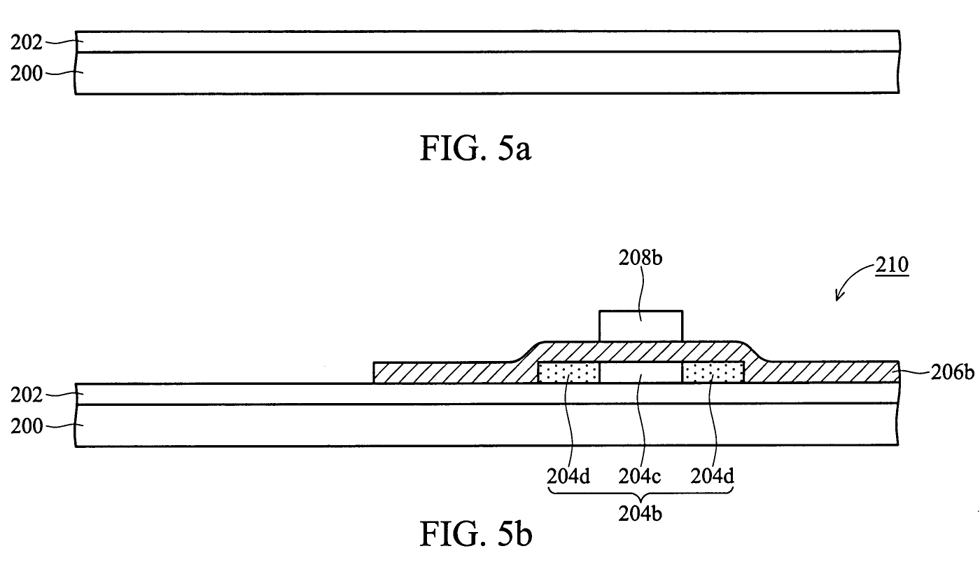

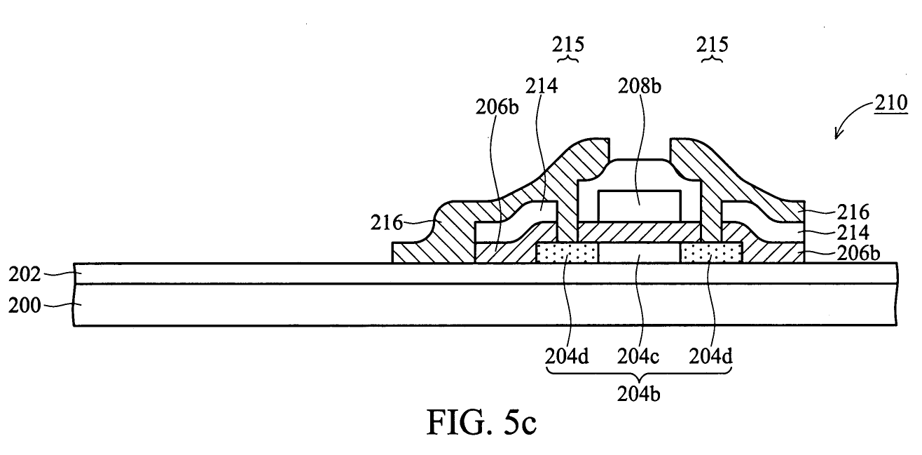

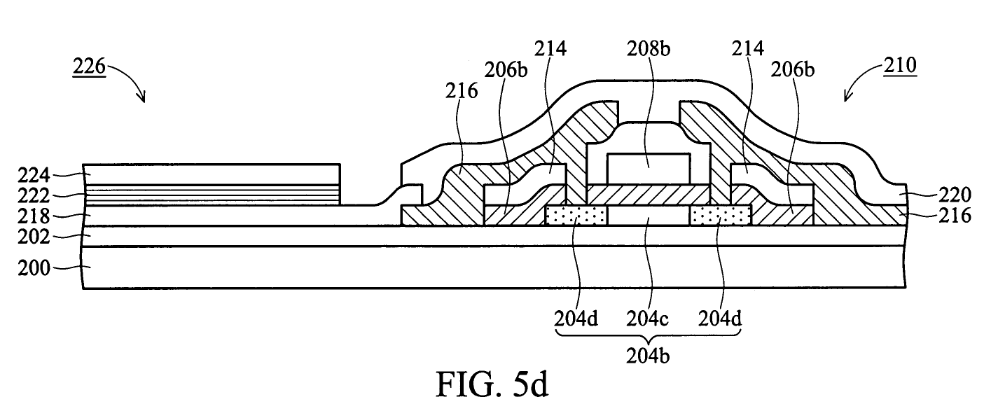

FIGS. 4a-4d and FIGS. 5a-5d respectively illustrate cross sections along the A-A′ line of the capacitor region C′ and the B-B′ line of the OLED region 101 in combination with the transistor region T2′ in FIG. 3 during a process of fabricating display pixels having higher aperture ratio according to the present invention.

In FIGS. 4a and 5a, a substrate 200 such as quartz glass, non alkaline glass or the like is provided. A buffer layer 202 is then formed on the substrate 200. The buffer layer can be, for example, a composite film of insulating material of oxide and nitride.

Next, the buffer layer 202 in the capacitor region C′ is selectively etched through the use of patterned mask and proper etching such as wet etching. A rugged buffer layer 202a is thus formed in the capacitor region C′ and can provide more surface area than the plane buffer layer 202 as shown in FIG. 5a. Preferably, the surface of the rugged buffer layer 202a can be rounded surface to provide a larger surface area.

In FIGS. 4b and 5b, a first conductive layer is conformably formed on the substrate 200. The first conductive layer can be, for example, a doped polysilicon layer. After a patterning step (not shown), a first conductive layer 204a is left on the rugged buffer layer 202a in the capacitor region C′ and another first conductive layer 204b covering a portion of the buffer layer 202 in the transistor/OLED region. Here, the first conductive layer 204a in the capacitor region C′ is also shown with a rugged surface.

Next, a dielectric layer is conformably formed on the substrate 200. The dielectric layer can be, for example, an oxide layer, a nitride layer or even a high-K dielectric layer. Material of the high-K dielectric layer can be, for example, Ta₂O₅, (Ba, Sr)TiO₃ (BST), PbZrTiO₃ (PZT) or the like. After a patterning step, a dielectric layer 206a having a rugged surface is formed on the first conductive layer 204a and another dielectric layer 206b is left over the first conductive layer 204b and portions of adjacent buffer layer 202 thereof.

Next, a second conductive layer is conformably formed on the substrate 200, covering the dielectric layers 206a, 206b and the exposed buffer layer 202. The second conductive layer can be a metal layer of tungsten (W) or tantalum (Ta), for example. After a proper patterning step, second conductive layers 208a, 208b are respectively formed over a portion of the dielectric layer 206b and the whole dielectric layer 206a. Next, a source/drain implantation (not shown) is performed to implant proper dopants into the first conductive layer 204b not covered by the second conductive layer 208b using the second conductive layer 208b as an implant mask. Channel region 204c and source/drain regions 204d are thus formed in the first conductive layer 204b. Here, a transistor 210 and a capacitor 212 are thus formed on the substrate 200 of different regions. The capacitor 212 has a rugged surface that improves unit capacitance thereof and size of the capacitor region is thus reduced.

In FIGS. 4c and 5c, an insulating layer 214 is then formed on the substrate 200 to cover only the transistor 210. The insulating layer can be, for example, an oxide layer. In the insulating layer 214, contact holes 215 are also formed in the relative position above the source/drain regions 204d during the patterning thereof. Next, a third conductive layer 216 is respectively formed on both sides of the transistor 210 and in the contact holes 215 formed therein to form source/drain connections to other sequentially formed devices.

In FIG. 4d and 5d, a fourth conductive layer 218 is formed on the substrate 200 and covers a portion of the third conductive layer 216 of the transistor 210, as an anode. Material of the fourth conductive layer can be indium tin oxide (ITO), indium-doped zinc oxide (IZO), zinc oxide (ZnO) or the like. A insulating layer 220 is then formed on the substrate 200 to blanketly cover the capacitor 212, the transistor 210 and a portion of the fourth conductive layer 218. Next, a shadow mask is used to selectively form an organic luminescent layer 222 and a cathode metal layer 224 on the exposed fourth conductive layer 218 on the substrate 200. Here, an organic light emitting diode (OLED) 226 connected to the transistor 210 is thus formed and the AM-OLED process of the invention is completed.

As shown in FIGS. 4d and 5d, devices such as the transistor 210, the capacitor 212 and the OLED 226 constituting an OLED display pixel are schematically illustrated. Due to the improved unit capacitance provided by the rugged structure of the capacitor 212, size of the capacitor region is reduced to increase surface area of the OLED region. Finally, display pixels having higher aperture ratio can be thus formed, as shown in FIG. 3.

### Embodiment 2

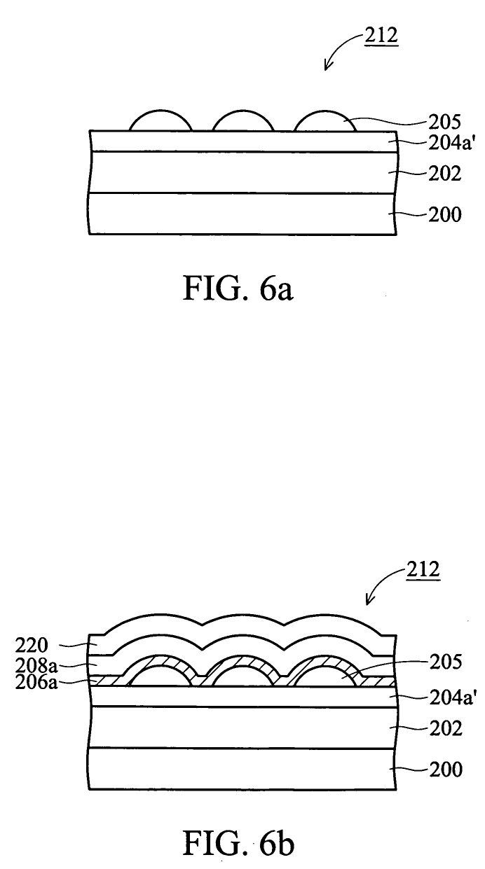

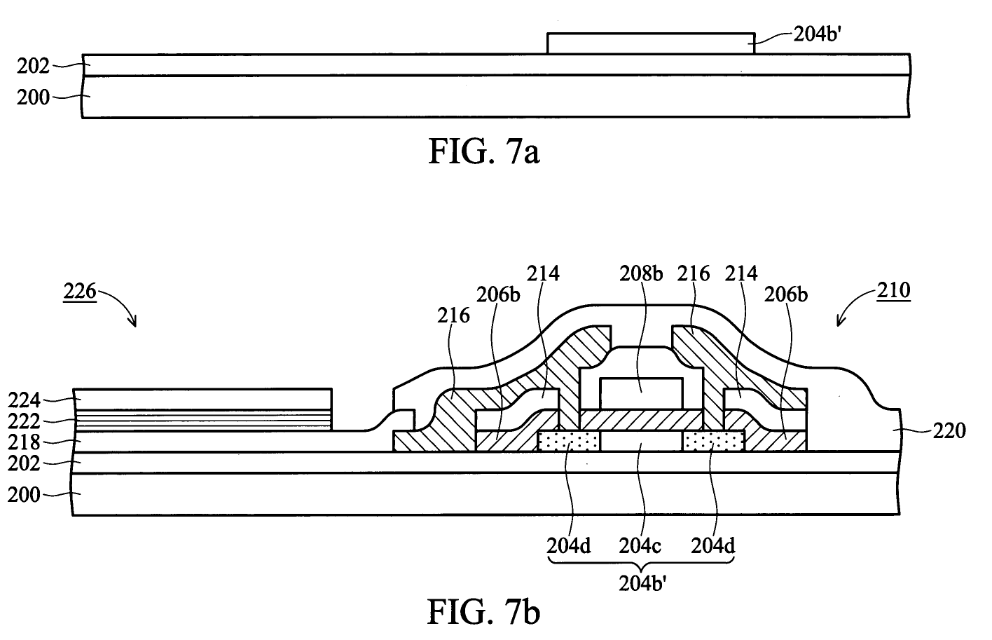

FIGS. 6a-6b and FIGS. 7a-7b respectively illustrate cross sections along the A-A′ line of the capacitor region C′ and the B-B′ line of the OLED region 101 in combination with the transistor region T2′ in FIG. 3 during a process for fabricating display pixels having higher aperture ratio according to the present invention.

In FIGS. 6a and 7a, a substrate 200 such as quartz glass, non alkaline glass, or the like, is provided. A buffer layer 202 is then formed on the substrate 200. The buffer layer can be, for example, a composite film of insulating material of oxide and nitride.

Next, a first conductive layer is conformably formed on the substrate 200. The first conductive layer is, for example, a doped polysilicon layer. After a patterning step, a first conductive layer 204a′ is left on the buffer layer 202 in the capacitor region C′ and another first conductive layer 204b′ formed on a portion of the buffer layer 202 in the transistor/OLED region.

Next, a plurality of overhangs 205 are then selectively formed on portions of the surface of the first conductive layer 204a′. These overhangs 205 can be, for example, hemispherical grained silicon (HSG) formed by conventional HSG fabrication. Thus, a rugged surface is formed on the first conductive layer 204a′, providing additional surfaces for increasing unit capacitance thereof. As described, surfaces of the HSG overhangs 205 are preferably rounded to form a larger surface area thereon.

Moreover, sequential fabricating steps can follow those illustrated in FIGS. 4b to 4d and FIGS. 5b to 5d of the first embodiment and are not repeated here, for simplicity.

In FIGS. 6b and 7b , devices such as the transistor 210, the capacitor 212 and the OLED 226 constituting an OLED display pixel are thus formed and illustrated. Due to the improved unit capacitance provided by the rugged surface in the capacitor 212, size of the capacitor region is reduced to provide additional surface for the OLED region. Finally, display pixels having higher aperture ratio are thus obtained, as shown in FIG. 3.

### Embodiment 3

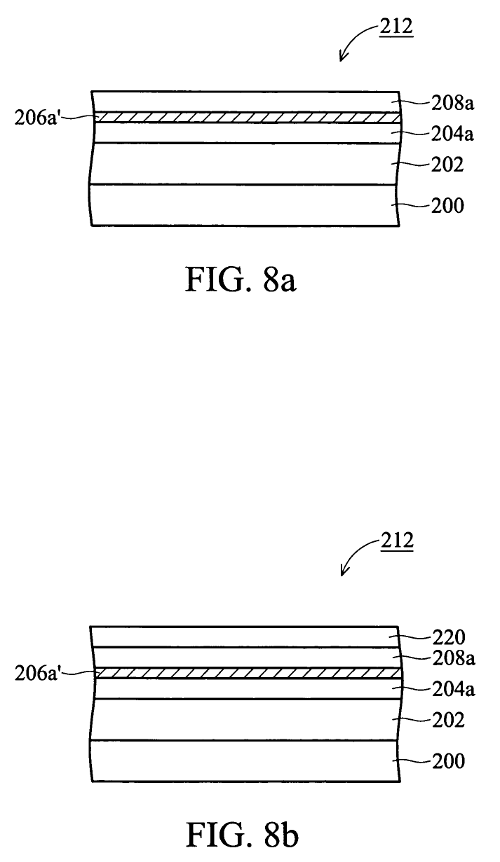

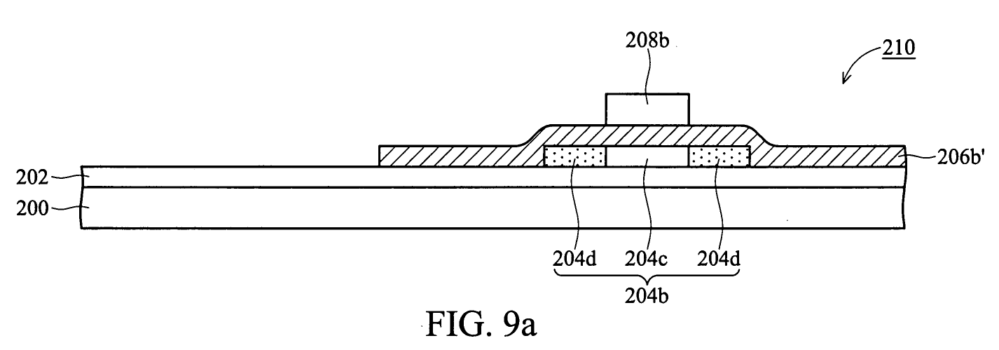

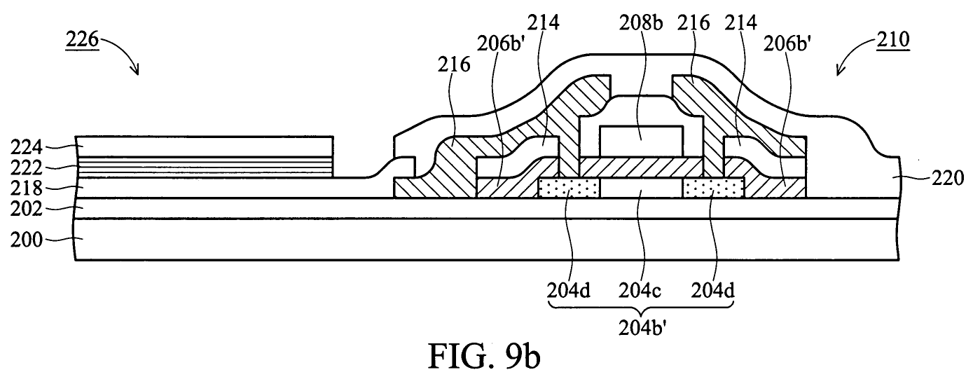

FIGS. 8a-8b and FIGS. 9a-9b respectively illustrate cross sections along the A-A′ line of the capacitor region C′ and the B-B′ line of the OLED region 101 in combination with the transistor region T2 in FIG. 3 during a process of fabricating display pixels with higher aperture ratio according the present invention.

In FIGS. 8a and 9a, a substrate 200 such as quartz glass, non alkaline glass or the like is provided. A buffer layer 202 is then formed on the substrate 200. The buffer layer 202 can be, for example, a composite film of insulating material such as oxide and nitride.

Next, a first conductive layer is conformably formed on the substrate 200. The first conductive layer is, for example, a doped polysilicon layer. After a patterning step (not shown), a first conductive layer 204a is left on the buffer layer 202 in the capacitor region C′ and another first conductive layer 204b is formed on a portion of the buffer layer 202 in the transistor/OLED region.

Next, a high-k dielectric layer is conformably formed on the substrate 200. Material of the high-K dielectric layer can be, for example, Ta₂O₅, BST, PZT or the like. After a patterning step, a high-k dielectric layer 206a′ is left on the first conductive layer 204a and the other high-k dielectric layer 206b′ is left over the first conductive layer 204b and covers portions of the adjacent buffer layer 202 thereof.

Next, a second conductive layer is conformably formed on the substrate 200, covering the dielectric layers 206a, 206b and the exposed buffer layer 202. The second conductive layer can be a metal layer of tungsten (W) or tantalum (Ta), for example. After a patterning step, second conductive layers 208a, 208b are respectively formed over a portion of the high-k dielectric layer 206b′ and the high-K dielectric layer 206a′. Next, a source/drain implantation (not shown) is performed to implant proper dopants into the first conductive layer 204b not covered by the second conductive layer 208b using the second conductive layer 208b as an implant mask. Channel region 204c and source/drain regions 204d are thus formed in the first conductive layer 204b. Here, a transistor 210 and a capacitor 212 are thus formed on the substrate 200. The capacitor 212 using high-k dielectric layer improves unit capacitance thereof and the surface area needed for the capacitor region is thus reduced.

Moreover, the sequential fabricating steps can follow up those steps illustrated in FIGS. 4c to 4d and FIGS. 5c to 5d of the first embodiment and are not repeated here, for simplicity.

In FIGS. 8b and 9b, devices such as the transistor 210, the capacitor 212 and the OLED 226 constituting an OLED display pixel are thus formed and illustrated. Due to the improved unit capacitance by the high-k dielectric in the capacitor 212, size of the capacitor region is reduced and additional surface for the OLED region is thus obtained. Finally, display pixels having higher aperture ratio can be thus obtained, as shown in FIG. 3.

As shown in FIGS. 3, 4d, and 6b, the prevent invention provides a display pixel having higher aperture ratio. The display pixel of the invention includes a capacitor and an organic light emitting diode formed over a substrate, wherein the capacitor comprises a first conductive layer, a dielectric layer and a second conductive layer stacked over the substrate, respectively having a rugged surface and a transistor connecting the capacitor and the organic light emitting diode formed over the substrate. In addition, the prevent invention provides another display pixel having higher aperture ratio, having dielectric layer of high-k dielectric, as shown in FIG. 8b.

In the present invention, the aperture ratio in display pixels of an AM-OLED display is improved through reduction of the capacitor region therein. Reduction of the capacitor region is achieved by forming rugged capacitor and/or the use of high-k dielectric therein. Measures described in these embodiments can be respectively applied or applied in combination. Due to the reduction of the capacitor region, additional surface area is obtained for forming the OLED device and aperture ratio of a display pixel is increased. Moreover, the high-k dielectric layer using material such as such as Ta₂O₅, BST, PZT or the like also increases the unit capacitance thereof.

In one embodiment of the present invention, the rugged surface in the capacitor region is formed through etching of the buffer layer.

In another embodiment of the present invention, the rugged surface in the capacitor region can be provided by additionally formed hemispherical structures in the capacitor.

In a third embodiment of the present invention, unit capacitance in the capacitor region is increased by only the use of high-k dielectric in the capacitor region.

In the display pixels formed according to methods of the present invention, aperture ratio is increased and power consumption thereof is also improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a display pixel, comprising the steps:
providing a substrate;
simultaneously forming a transistor and a rugged capacitor on adjacent portions of the substrate, wherein the rugged capacitor comprises a first conductive layer, a dielectric layer and a second conductive layer stacked over the substrate, respectively having a rugged surface; and
forming an organic light emitting diode (OLED) on a portion of the substrate adjacent to the transistor, wherein an anode thereof electrically connects to the transistor.

2. The method as claimed in claim 1, wherein the rugged surfaces are substantially rounded surfaces.

3. The method as claimed in claim 1, wherein the first conductive layer having a rugged surface comprises a plane conductive layer with a plurality of overhangs formed thereon.

4. The method as claimed in claim 3, wherein the overhangs comprise hemispherical grained silicon.

5. The method as claimed in claim 1, wherein the dielectric layer is a high-k dielectric layer comprising Ta₂O₅, BST or PZT.

6. A method for fabricating a display pixel, comprising the steps of:
providing a substrate;
simultaneously forming a transistor and a stacked capacitor on adjacent portions of the substrate, wherein the capacitor comprises a first conductive layer, a high-k dielectric layer and a second conductive layer stacked over the substrate; and
forming an organic light emitting diode (OLED) on a portion of the substrate adjacent to the transistor, wherein an anode thereof electrically connects to the transistor.

7. The method as claimed in claim 6, wherein the high-k dielectric layer comprises Ta₂O₅, BST or PZT.

8. A method for fabricating a display pixel, comprising the steps of:
providing a substrate having a buffer layer formed thereon, wherein the substrate comprises at least a transistor region, a capacitor region and an organic light emitting diode (OLED) region;
forming rugged surfaces on the buffer layer in the capacitor region;
respectively forming a first conductive layer over the buffer layer in the capacitor portion and over a portion of the buffer layer of the transistor region;
respectively forming a dielectric layer over the first conductive layer in the capacitor region and the transistor region;
respectively forming a second conductive layer over the dielectric layer in the capacitor region and a portion of the dielectric layer in the transistor region to cover a portion of the first conductive layer therebelow;
implanting the first conductive layer not covered by the second conductive layer in the transistor region to form a pair of source/drain regions and a channel region therein, simultaneously forming a rugged capacitor in the capacitor region and a transistor in the transistor region;
forming source/drain contacts over and on both sides of the transistor, wherein the source/drain contact at one side extends and covers a portion of adjacent buffer layer;
forming a third conductive layer on the buffer layer in the OLED region and a portion of the buffer layer in the transistor region, covering a portion of the source/drain contact covering the buffer layer; and
sequentially forming an organic luminescent layer and a metal cathode layer on the third conductive layer to form an organic light emitting diode (OLED) in the OLED region.

9. The method as claimed in claim 8, wherein the rugged surfaces are substantially rounded surfaces.

10. The method as claimed in claim 8, wherein the method of forming rugged surfaces comprises the steps of:
covering the buffer layer with a patterned mask to partially expose portions of the buffer layer of the capacitor region;
removing portions of the buffer layer from the exposed surfaces; and
removing the patterned mask to form the buffer layer having rugged surfaces.

11. The method as claimed in claim 8, wherein the dielectric layer is a high-k dielectric layer comprising Ta₂O₅, BST or PZT.

12. A method for fabricating a display pixel, comprising the steps:
providing a substrate having a buffer layer formed thereon, wherein the substrate comprises at least a transistor region, a capacitor region and an organic light emitting diode (OLED) region;
respectively forming a first conductive layer over the buffer layer in the capacitor portion and a portion of the buffer layer of the transistor region;
forming overhangs on portions of the first conductive layer in the capacitor region;
respectively forming a dielectric layer over the first conductive layer in the capacitor region and the transistor region, covering the overhangs thereon;
respectively forming a second conductive layer over the dielectric layer in the capacitor region and over a portion of the dielectric layer in the transistor region to cover a portion of the first conductive layer therebelow;
implanting the first conductive layer not covered by the second conductive layer in the transistor region to form a pair of source/drain regions and a channel region therein, simultaneously forming a rugged capacitor in the capacitor region and a transistor in the transistor region;
forming source/drain contacts over and on both sides of the transistor, wherein the source/drain contact at one side extends and covers a portion of adjacent buffer layer;
forming a third conductive layer on the buffer layer in the OLED region and a portion of the buffer layer in the transistor region, covering a portion of the source/drain contact covering the buffer layer; and
sequentially forming an organic luminescent layer and a metal cathode layer on the third conductive layer to form a organic light emitting diode in the OLED region.

13. The method as claimed in claim 12, wherein the overhangs have substantially rounded surfaces.

14. The method as claimed in claim 13, wherein the overhangs comprise hemispherical grained silicon.

15. The method as claimed in claim 12, wherein the dielectric layer is a high-k dielectric layer comprises Ta₂O₅, BST or PZT.

16. A display pixel, comprising:
a capacitor and a organic light emitting diode formed over a substrate, wherein the capacitor comprises a first conductive layer, a dielectric layer and a second conductive layer stacked over the substrate, respectively having a rugged surface; and
a transistor connecting the capacitor and the organic light emitting diode formed over the substrate.

17. The display pixel as claimed in claim 16, wherein the rugged surfaces are substantially rounded surfaces.

18. The display pixel as claimed in claim 16, wherein the first conductive layer with a rugged surface comprises a plane conductive layer and a plurality of overhangs formed thereon.

19. The display pixel as claimed in claim 18, wherein the overhangs are hemispherical grained silicon.

20. The display pixel as claimed in claim 16, wherein the dielectric layer is a high-k dielectric layer comprises Ta₂O₅, BST or PZT.
